(19) United States
(12) Patent Application Publication
(10) Pub. No.: US 2006/0104341 A1
(43) Pub. Date: May 18, 2006

(54) Systems and methods for providing training data

(76) Inventors: David Patrick Magee, Plano, TX (US); Michael Oliver Polley, Garland, TX (US)

Correspondence Address: TEXAS INSTRUMENTS INCORPORATED, P O BOX 655474, M/S 3999, DALLAS, TX, 75265, US

(21) Appl. No.: 10/989,927

(22) Filed: Nov. 16, 2004

(51) Int. Cl. H03K 5/159

(52) U.S. Cl. 375/231

(57) ABSTRACT

The disclosure relates to systems and methods for providing training data in packets transmitted to one or more receivers. The systems and methods measure at least one receiver performance metric associated with operating conditions of a given receiver. The at least one receiver performance metric is compared to at least one receiver performance metric level to determine training data to be provided in one or more subsequently transmitted packets.

### TECHNICAL FIELD

The present invention generally relates to communication systems and in particular to systems and methods for providing training data.

### BACKGROUND OF THE INVENTION

Various types of distortion and noise are introduced into data signals that are transmitted wirelessly over a given communication path. The distortion and noise are due to interference with other signals within the same frequency range and also due to multipath dispersions. Multipath dispersions occur when signals propagate along different or reflected paths through a transmission medium to a receiving destination. Generally, a signal or beam travels along a main or direct line-of-sight transmission path, while reflected signals travel along various reflected paths. Each reflected path has an associated delay and the overall effects of all such signals are a combination of the main signal and a plurality of reflected or delayed signals. Therefore, the signal received is usually not the same as the original signal transmitted, and when the signal is demodulated and decoded, errors in the original transmitted data may often result.

The effect of the multipath scattering is to alter or distort the received signal spectrum when compared to the spectrum as transmitted. In general, the effects are different at various frequencies across the signaling band. At some frequencies, the multipath signals add constructively to result in an increased signal amplitude, while at other frequencies the multipath signals add destructively (out of phase) to cancel or partially cancel the signal, resulting in reduced signal amplitude.

Wireless communication systems have been designed to compensate for the deleterious effects of multipath dispersion. Many wireless systems and some wired systems employ a channel estimation procedure to determine the effects the transmission environment has on the transmitted data signals. The channel estimation procedure can utilize training signals of known magnitude and phase to compensate for signal changes due to the transmission environment. The training signals can be transmitted prior to transmission of the data signals or interspersed in the data signals. The training signals can be analyzed to determine the effects of the environment on the transmitted signal and this information utilized to adjust the data signals appropriately.

However, within a given cell of a wireless communication network, operating conditions can vary greatly from location to location. For example, multi-path, interference, obstructions and other factors can produce regions where channel conditions are better in some location than in others. These effects impact the signal-to-noise ratio (SNR) at the receiver, which in turn affects the ability of the receiver to decode the transmitted data.

### SUMMARY OF THE INVENTION

Systems and methods are disclosed for determining training data to be provided in a packet for a given receiver. The systems and methods determine at least one receiver performance metric associated with operating conditions of a given receiver. The at least one receiver performance metric can be compared to at least one performance metric level to determine training data to be provided in at least one subsequent data packet to be transmitted to the receiver. The performance metric can be measured at a given receiver or an access point associated with the given receiver.

In accordance with an aspect of the present invention, a communication system is provided. The communication system comprises a metric analyzer that measures at least one performance metric associated with at least a portion of a received data packet. The communication system also comprises an additional training determination component that determines additional training data to be transmitted in at least one subsequent data packet based on the measured at least one performance metric.

In accordance with yet another aspect of the present invention, a packet structure is provided comprising a preamble portion having a plurality of short training symbols and a plurality of long training symbols, a header portion having a plurality of parameters defining the packet structure, and a data portion having a plurality of data symbols. The packet structure also includes an additional training data portion for providing a plurality of additional training data in the packet structure. The additional training data portion can be part of the preamble or the data portion of the packet structure.

In accordance with a further aspect of the present invention, a methodology is provided for determining training data to be provided in data packets transmitted to a receiver. The method comprises measuring at least one performance metric associated with data received at a receiver, comparing the at least one performance metric to at least one predetermined performance metric level, and determining training data to be provided in transmitted data packets to the receiver based on the comparison.

In accordance with yet a further aspect of the present invention, a methodology is provided for transmitting data packets with training data. The method comprises receiving an indication of training data to be provided in subsequently transmitted data packets for a given receiver, building a data packet to be transmitted to the given receiver with the determined training data embedded in the data packet, and transmitting the data packet with the determined training data to the given receiver.

### BRIEF DESCRIPTION OF THE DRAWINGS

FIG. 1 illustrates a block diagram of a receiver in accordance with an aspect of the present invention.

FIG. 2 illustrates a block diagram of an access point in accordance with an aspect of the present invention.

FIG. 3 illustrates a conventional packet structure.

FIG. 4 illustrates a packet structure in accordance with an aspect of the present invention.

FIG. 5 illustrates a packet structure in accordance with another aspect of the present invention.

FIG. 6 illustrates a block diagram of an access point that performs metric performance measurements in accordance with an aspect of the present invention.

FIG. 7 illustrates a block diagram of a multi-antenna receiver in accordance with an aspect of the present invention.

FIG. 8 illustrates a methodology for determining training data for a given receiver in accordance with an aspect of the present invention.

FIG. 9 illustrates a methodology for building and transmitting packets with training data in accordance with an aspect of the present invention.

FIG. 10 illustrates another methodology for determining training data in accordance with an aspect of the present invention.

### DETAILED DESCRIPTION

The present invention will be described with reference to systems and methods for determining training data to be provided in a packet for a given receiver associated with a wireless communication system. The systems and methods determine at least one receiver performance metric associated with operating conditions of a given receiver. The at least one receiver performance metric can be, for example, signal-to-noise ratio (SNR), signal-to-interference plus noise ratio (SINR), frame error rate (FER), bit error rate (BER) or other receiver performance metrics. The at least one receiver performance metric is employed to determine the training data to provided in subsequent packets transmitted to the receiver.

The determined training data can be in the form of a number and/or type of additional training symbols. Additionally, the training data can be in the form of a number and/or type of additional training tones (e.g. pilot tones) embedded in data symbols. The different types of training tones or symbols can include, for example, time orthogonal, time switched, frequency orthogonal and frequency switched designs. The at least one metric can be determined at a given receiver or at an access point associated with the receiver.

The additional training data is employed to improve the channel estimates at a given receiver, since each receiver in a wireless communication system is exposed to different operational conditions. Therefore, to mitigate degradation of receiver performance caused by different operating conditions, the receiver can specify the additional training desired to improve the channel estimates. Channel estimate results are improved with more training data because additional training symbols enable more averaging for better channel estimation results and additional training tones enable improved channel tracking capabilities during data symbols.

The use of the term additional training is employed in the following illustrated examples to refer to training data that is in addition to a fixed amount of training of a given wireless communication standard. It is to be appreciated that additional training data can be dynamically modified to be less than or greater than the additional training data provided in previous packets as operating conditions of a receiver or communication device change. It is also to be appreciated that training data for a given standard can be variable, such that an initial amount of training data can be provided based on the given standard. Therefore, the initial amount of training data can be adjusted to be less than or greater than an initial amount of training data defined by the standard.

FIG. 1 illustrates a functional block diagram of a wireless receiver system 10 in accordance with one aspect of the present invention. The wireless receiver can be associated with a mobile communication unit (MCU) within a wireless system. The MCU can include a transmitter (TX) (not shown) for communicating with other mobile communication units through an access point or base station. A data signal or burst is received by an antenna 14, which captures the data signal and transfers the data signal to a front end processing component 12. A data signal or burst is a transmission signal carrying data. The data signal or burst can also include other information such as packet information, training information and calibration information.

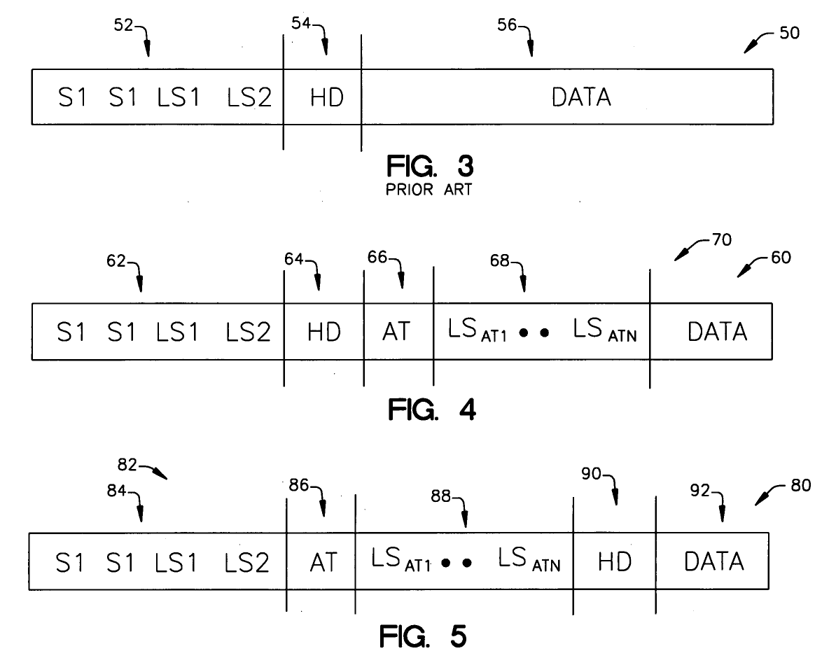

For example, FIG. 3 illustrates a conventional wireless packet structure 50 comprising a data signal. The conventional wireless packet structure can be a packet that conforms to a wireless standard, such as IEEE 802.11(a), IEEE 802.11(b), or IEEE 802.11(g). The packet structure 50 includes a preamble portion 52, a header portion 54 and a data portion 56. The preamble portion 52 includes a plurality of short training symbols (S1, S2), and a plurality of long training symbols (LS1, LS2). The plurality of short training symbols are employed by a digital preprocessor 18 to determined the amount of gain adjustment associated with one or more amplifiers in the analog front end 12. The plurality of long training symbols are employed to perform channel estimation, which determines the amount of phase rotation and magnitude perturbation applied to the tones associated with the header portion 54 and the data portion 56 of the packet 50 by the channel. The number of the plurality of long training symbols are fixed based on the associated wireless standard of the packet, regardless of the varying operation conditions associated with a given receiver.

The header portion 54 includes a plurality of parameters that define the packet structure 50. The plurality of parameters include at least the coding rate, length, and parity associated with the packet structure 50. The data portion 56 includes a plurality of data symbols. The number of allowable data symbols can be fixed based on the wireless standard of the packet structure 50. Additionally, other information such as service data may reside in the data portion 56 of the packet structure 50.

Referring again to FIG. 1, the front end processing component 12 amplifies the data signal via a low noise amplifier (LNA) or other amplifier type, converts the data signal to an intermediate frequency (IF) and filters the data signal to eliminate signals that are outside of the desired frequency band. It is to be appreciated that many variations in receiver front end processing exist. For example, some receiver front end processing includes utilizing multiple IF frequencies and successive frequency conversions. Additionally, some receivers provide direct radio frequency (RF) to baseband conversion without IF stages. The front end processing component 12 feeds one or more analog-to-digital (A/D) converters 16 that sample the data signal and provide a digitized signal output. The front end processing component 12 can provide automatic gain control (AGC) to maintain the signal strength relative to the one or more A/D converters 16.

The digitized signal output of the one or more A/D converters 16 is then provided to the digital preprocessor 18. The digital preprocessor 18 provides additional filtering of the digitized signals and decimates the samples of the digitized signal. The digital preprocessor 18 then performs a Fast Fourier Transform (FFT) on the digitized signal. The FFT on the digitized signal converts the signal from the time domain to the frequency domain so that the frequencies or tones carrying the data can be provided. The digital processor 18 can also adjust the gain of the LNA at the analog front end 12 based on the processed data, and include logic for detection of packets transmitted to the receiver 10. The exact implementation of the digital preprocessor 18 can vary depending on the particular receiver architecture being employed to provide the frequencies or tones carrying the data. The frequencies and tones can then be demodulated and/or decoded. However, the demodulation of the tones requires information relating to the wireless channel magnitude and phase at each tone. The effects of the dispersion caused by the channel need to be compensated prior to decoding of the signal, so that decoding errors can be minimized. This is achieved by performing channel estimation.

Therefore, the digital preprocessor 18 provides the frequencies or tones to a channel estimator 20. The channel estimator 20 determines a channel estimate employing training tones embedded in the long training symbols and/or training tones embedded in data symbols of the data packet. The channel estimator 20 employs the long training symbols and/or training tones to perform channel estimation and to determine the amount of phase rotation and magnitude perturbation applied to the tones by the channel. Since the training tones are transmitted with known magnitude and phase, the channel response at the training tones is readily determined. For example, the known channel response at the training tones can then be interpolated in the frequency domain to determine the channel response at the data tones. A cyclic interpolation procedure can be employed.

The channel estimate is provided to a data demodulator 22 for demodulation of the digital data signal. The demodulated data signal is then transferred to data postprocessing component 26 for further signal processing. The data postprocessing component 26 decodes the demodulated data signal and performs forward error correction (FEC) utilizing the information provided by the data demodulator in addition to providing block or packet formatting. The data postprocessing component 26 then outputs the data.

A metric analyzer 24 is employed to determine at least one performance metric associated with processing of the data signal. For example, the metric analyzer 24 can be associated with the channel estimator 20 or data demodulator 22 for determining SNR or SINR of the received data signal. Alternatively, the metric analyzer 24 can be associated with the data postprocessing 26 to determine FER or BER. The metric analyzer 24 provides the measured performance metric data to a training determination component 28.

The training determination component 28 compares the measured performance metric with one or more predetermined performance metric levels to determine the training data to be transmitted in subsequent packets transmitted to the receiver 10. The training data can be a number and/or type of additional training symbols, and/or a number and/or type of additional training tones to be provided in data symbols for subsequent data packets. The training data can be an adjustment to an initial amount of training data, such that the adjustment can be more or less training data than the initial amount. The training determination component 28 can be an algorithm executing in a processor, a hardware device or a combination of hardware and software. The training determination component 28 provides an indication of the determined training data to a transmitter (TX) associated with the receiver, such as a transmitter in a MCU with the receiver. The transmitter transmits the indication of the training data to be provided in subsequently transmitted packets by an associated access point or base station that is providing data packets to the receiver 10.

For example, different measured levels of a given performance metric can be employed to determine the training data to be provided in subsequent packets. The communication unit associated with the receiver then transmits a communication to the access point or base station indicating the training data to be provided in subsequent transmitted packets to the receiver. The access point or base station will then transmit subsequent packets to the receiver with a specified number and/or type of training symbols and/or tones indicated by the receiver 10, until a further communication is received from the communication device associated with the receiver 10. The specified number and/or type of training symbols and/or tones can be an adjustment of training data that is more or less than training data provided in a previous data packet. This process can occur at initialization or be dynamically performed, such that changes in performance metric measurements caused the number and/or type of training symbols and/or tones to be periodically modified.

The specifying of training data in accordance with an aspect of the invention can be employed on a variety of different communication methods and devices utilizing a channel estimation procedure. One particular communication method is referred to as multicarrier modulation. One special case of multicarrier modulation is referred to as Orthogonal Frequency Division Multiplexing (OFDM). In general, OFDM is a block-oriented modulation scheme that maps a number of data constellation points onto a number of orthogonal carriers separated in frequency by BW/N, where BW is the bandwidth of the OFDM symbol and N is the number of tones in the OFDM symbol. OFDM is a technique by which data is transmitted at a high rate by modulating several low bit rate carriers in parallel rather than one single high bit rate carrier. OFDM is particularly useful in the context of Wireless Local Area Network (WLAN), Digital Video Broadcasting (DVB), High Definition Television (HDTV) and also for Asymmetric Digital Subscriber Lines (ADSL) systems. OFDM can also be useful in satellite television systems, cable television, video-on-demand, interactive services, mobile communication devices, voice services and Internet services.

In transmission of a data signal, an OFDM modulator converts a serial data stream into a block of N complex carriers. These carriers, of which phase and amplitude can be modulated, correspond to a time domain waveform that is generated using an Inverse Fast Fourier Transform (IFFT). The data signal is then amplified and transmitted over a wireless channel to a receiver. At the receiver end, a data signal or data burst is received in the time domain and converted back into the frequency domain employing a FFT for extraction of the frequencies (e.g., tones) from the data burst. The frequency domain signal is comprised of a plurality of data tones, training tones and zero tones. The training tones are transmitted at known magnitude and phase and employed in determining the channel estimate for use in compensating the data tones due to the effects of the channel on the tones.

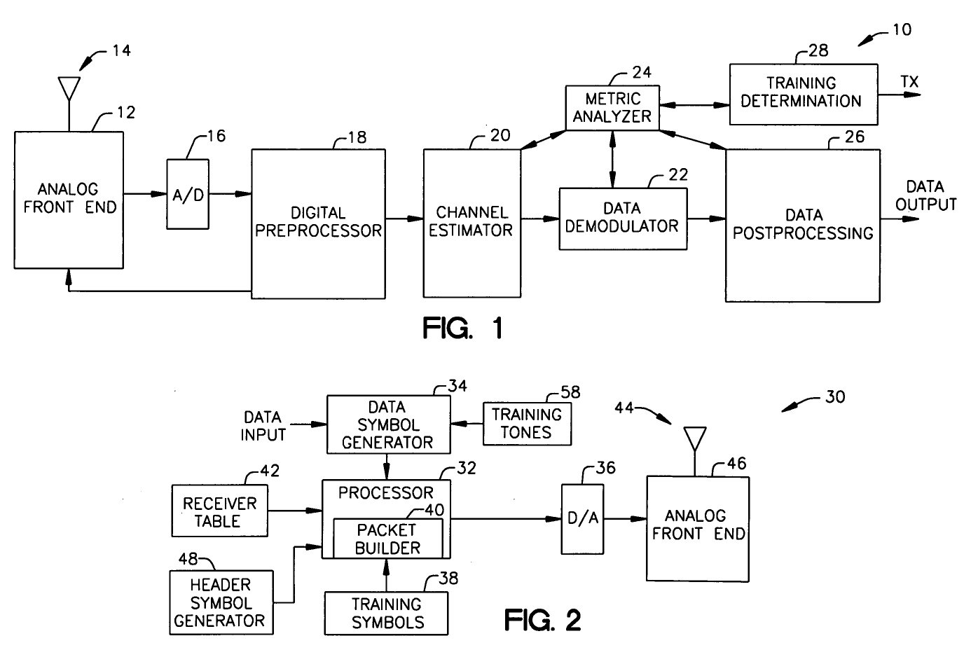

FIG. 2 illustrates a transmitter 30 associated with a communication device that transmits packets in accordance with an aspect of the present invention. The transmitter 30 can be associated with an access point or base station of a wireless communication system. The transmitter 30 includes a processor 32 with a packet builder component 40. The packet builder component 40 builds data packets for transmission to one or more receivers in a wireless communication system. The data packets can be data packets that conform to one or more wireless communication standards. The system 30 includes a header symbol generator 48 that provides the packet builder 40 with a header symbol or symbols. The system 30 also includes a data symbol generator that receives a data input and builds data symbols to be provided to the packet builder 40.

Additionally, the data symbol generator can build data symbols with training tones 58. Additionally, the packet builder 40 employs a plurality of training symbols 38 for embedding in transmission packets to the one or more receivers. The packet builder 40 provides training symbols in the data packet based on the communication format of the data packet. Additionally, the packet builder 40 can include additional training data requested by each of a plurality of receivers in the building the data packets. The additional training data can be in the form of additional training symbols and/or tones that can vary in number and/or type for each receiver, such that each training sequence can be similar or unique.

The processor 32 builds a receiver table 42 based on communications from the receiver specifying the training data that the receiver is to receive in subsequent packet transmission to the receiver. Upon transmitting a packet to a given receiver, the processor 32 extracts an indicator from the receiver table 42 that is associated with the given receiver. The processor 32 then retrieves the training symbols 38 and/or training tones 58 for the given receiver based on the indicator. The packet builder 40 then builds the packet using the training symbols and/or tones. In this manner, specific training data associated with each receiver can be employed for transmissions to receivers. The receiver table 42 can be periodically updated or modified based on new communications received from the one or more receivers indicating that the one or more receivers require a different number and/or type of training symbols and/or tones.

The packet builder 40 combines the training symbols with the symbols from the header symbol generator 48 and the data symbol generator 34 to build the desired packet. Additionally, the data symbol generator builds the data symbols with or without training tones 58. If the built packet is represented in the frequency domain, the processor 32 performs an IFFT (Inverse Fast Fourier Transform) to convert it into a time domain representation. Once the built packet is represented in the time domain, the processor 32 appends a cyclic prefix to each symbol and then provides the built packet to a D/A converter (D/A) 36. The D/A converter 36 converts the digital data to the analog domain for transmission by an analog front end 46. The analog front end 46 includes upmixers, filters and one or more power amplifiers coupled to an antenna 44 for wireless transmission to one or more receivers.

FIG. 4 illustrates a wireless packet structure 60 in accordance with an aspect of the present invention. The packet structure 60 can be employed in a packet that conforms to a wireless standard, such as IEEE 802.11(a), IEEE 802.11(b), or IEEE 802.11(g). The packet structure 60 includes a preamble portion 62, a header portion 64 and a data portion 70. The preamble portion 62 includes a plurality of short training symbols (S1, S2), and a plurality of long training symbols (LS1, LS2). The plurality of short training symbols are employed by a digital preprocessor to determined the amount of gain adjustment associated with one or more amplifiers in the analog front end. The plurality of long training symbols are employed for channel estimation at the receiver, which determines the amount of phase rotation and magnitude perturbation applied to the tones associated with the header portion and the data portion of the packet structure 60 by the channel. The header portion 64 includes a plurality of parameters that define the packet structure 60. The plurality of parameters includes at least the coding rate, length, and parity associated with the packet structure 60.

An additional training definition field (AT) 66, and a plurality of additional training symbols (LSAT1-LSATN) 68 are embedded in the data portion 70 of the packet structure 60, where N is greater than or equal to one. In this manner, the additional training symbols 68 and/or training tones in the data symbols can be employed in current wireless standards without modification of the associated wireless standard. The additional training definition field (AT) 66 defines the number and/or type of additional training symbols and/or tones of additional training in the packet 60. Alternatively, the additional training definition field (AT) 66 can define a given sequence of training symbols and/or tones that includes a set number of additional training symbols and/or tones of the same or different type. Each receiver and access point in the wireless communication system can be operative to determine a desired sequence of training symbols and/or tones for a respective receiver, such that a given receiver receives packets with training symbols and/or tones based on a measured level of one or more performance metrics associated with the given receiver.

FIG. 5 illustrates a wireless packet structure 80 in accordance with another aspect of the present invention. The packet structure 80 can be employed in a packet for a new or modified wireless standard that occurs in the future. The packet structure 80 includes a preamble portion 82, a header portion 90 and a data portion 92. The preamble portion 82 includes a plurality of short training symbols (S1, S2), and a plurality of long training symbols (LS1, LS2). The preamble portion 82 also includes an additional training definition field (AT) 86, and a plurality of additional training symbols (LSAT1-LSATN) 88 embedded in the preamble portion 82 of the packet structure 80, where N is greater than or equal to one. The additional training definition field 86 defines the number and/or type of additional training symbols and/or tones in the packet structure 80. Each receiver and access point in the wireless communication system can be operative to determine a desired sequence of training symbols and/or tones for a respective receiver, such that a given receiver receives packets with training symbols and/or tones based on a measured level of one or more performance metrics associated with the given receiver.

The header portion 90 includes a plurality of parameters that define the packet structure. The plurality of parameters include at least the coding rate, length, and parity associated with the packet structure. The data portion 92 includes data symbols associated with the packet structure 80. One or more data symbols can include embedded training tones. By providing additional training symbols in the preamble 82 and/or additional training tones in the data symbols, improved channel estimates can be obtained since more training symbols and/or tones can be employed during channel estimation.

FIGS. 4-5 illustrate two data packet structure formats that can be employed in accordance with the present invention. It is to be appreciated that there can be a variety of different packet structure formats that include additional training symbols and/or tones for improved channel estimation. For example, another packet structure format can provide an initial amount of training data in a data portion without having a dedicated training data portion in the preamble. The initial amount of training data can be adjusted to be more or less in subsequent packets base on the operating conditions for a given receiver.

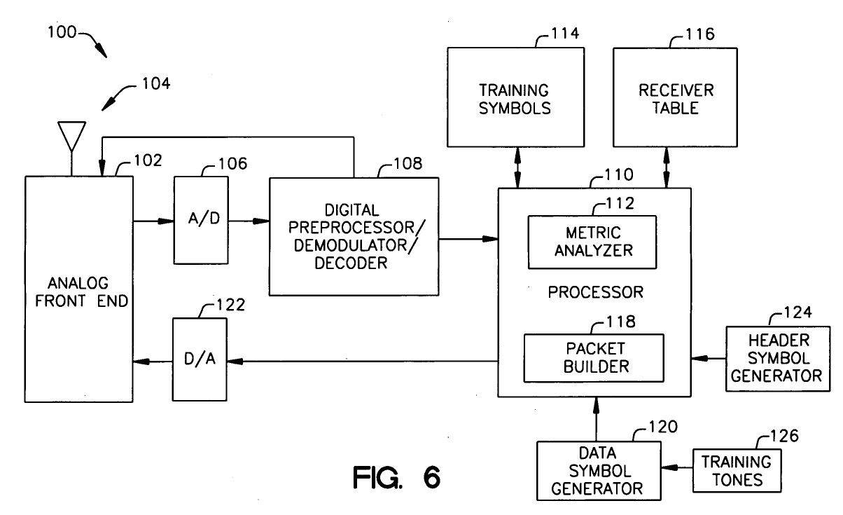

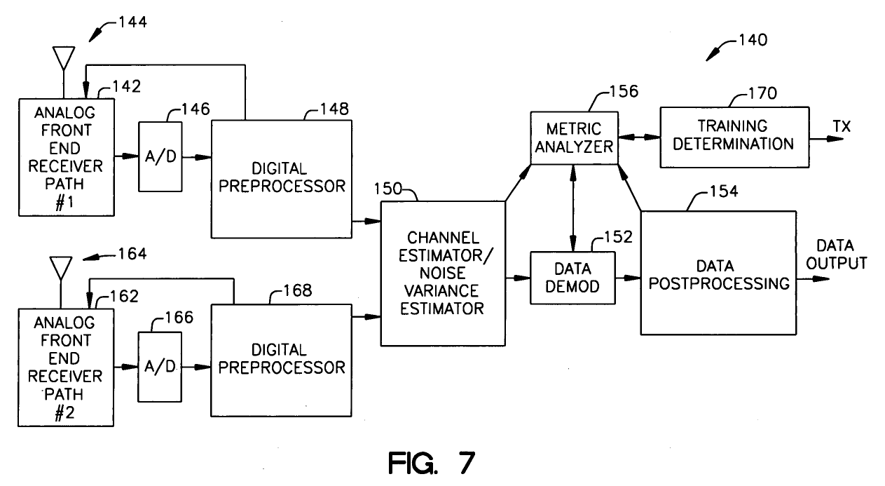

FIG. 6 illustrates an access point 100 that performs receiver performance metric analysis in accordance with an aspect of the present invention. The performance metric analysis is performed by a metric analyzer 112, which measures one or more metrics associated with receiver acknowledgement packets sent by a given MCU associated with a given receiver. For example, the SNR of the receiver acknowledgment packet measured at the access point 100 in a TDD system should be indicative of the SNR at the receiver since the channel is independent of direction. Thus, the measured metric associated with a given receiver can be compared to one or more metric threshold levels to determine the training data (e.g., number and/or type of training symbols and/or tones) to provide in one or more subsequent transmission packets transmitted by the access point 100 to the given receiver.

The access point 100 includes a receiver portion that receives communications from one or more MCUs through an antenna 104 coupled to an analog front end 102. The analog front end 102 can include amplifiers, filters and mixers to provide a reliable received signal to an A/D converter 106. The A/D converter 106 digitizes the analog data signal to provide a digitized data signal to a digital preprocessor/demodulator/decoder 108. The digital preprocessor/demodulator/decoder 108 performs similar functions as discussed with respect to the receiver 10 in FIG. 1. The digital preprocessed, demodulated and decoded data signal is then provided to a processor 110.

The processor 110 performs one or more performance metrics on the decoded data signal to determine one or more metrics associated with the receiver associated with the MCU that transmitted the data signal. Although the metric analyzer 112 is illustrated at the processor 110, it is to be appreciated that performance metric measurements can be performed at one or more different receiver stages, as illustrated in FIG. 1. The access point 100 then determines the training data that is to be embedded into subsequent packets for the given receiver based on the performance metric measurements. The processor 110 then stores an indicator for the given receiver in the receiver table 116 for use during subsequent packet transmissions to the receiver.

The transmitter portion of the access point 100 includes a packet builder 118. The packet builder 118 builds data packets for transmission to one or more receivers. The data packets can be data packets that conform to one or more wireless communication standards. Upon transmission of a data packet to a given receiver, the processor 110 employs the receiver table 116 to determine the training data to be associated with the given receiver.

The access point 100 includes a header symbol generator 124 that provides the packet builder 118 with a header symbol or symbols. The access point 100 also includes a data symbol generator 120 that receives a data input and builds data symbols to be provided to the packet builder 118. Additionally, the data symbol generator 120 can build data symbols with training tones 126. Additionally, the packet builder 118 employs a plurality of training symbols 114 for embedding in transmission packets to the one or more receivers. The packet builder 118 provides training symbols in the data packet based on the communication format of the data packet. Additionally, the packet builder 118 can include additional training data requested by each of a plurality of receivers in the building the data packets. The additional training data can be in the form of additional training symbols and/or tones that can vary in number and/or type for each receiver, such that each training sequence can be similar or unique. Furthermore, the training data can be an adjustment that is more or less than an initial amount of training data defined by a given standard.

The packet builder 118 combines the training symbols 114 with the header symbol or symbols and the data symbols with or without training tones 126 to build the packet with the selected training data. In this manner, a specific number and/or type of training symbols and/or tones can be employed for transmissions to receivers. The receiver table 116 can be periodically updated or modified based on new communications received from MCUs associated with the one or more receivers indicating that the one or more receivers require a different number and/or type of training symbols and/or tones. If the built packet is represented in the frequency domain, the processor 110 performs an IFFT (Inverse Fast Fourier Transform) to convert it into a time domain representation. Once the built packet is represented in the time domain, the processor 110 appends a cyclic prefix to each symbol and then provides the built packets to a D/A converter 122. The D/A converter 122 converts the digital data to the analog domain for transmission by the antenna 104 coupled to the analog front end 102.

It is to be appreciated that the present invention can be employed in wireless communication systems employing multiple input-multiple output (MIMO) systems in which base stations transmit data employing multiple transmitters and receivers receive transmission data using multiple receiving antennas. The data received in a multiple antenna receiver is typically transmitted using spatial diversity or time diversity. Multiple antenna receivers are more sensitive to environmental effects than are single antenna receiver systems. Additionally, good channel estimates are challenging when trying to keep the preamble length short in MIMO systems.

FIG. 7 illustrates a multiple antenna receiver 140 in accordance with an aspect of the present invention. The multiple antenna receiver 140 includes a first antenna 144 with a first associated receiver path and a second antenna 164 with a second associated receiver path. The first receiver path includes a first analog front end 142, a first A/D converter 146 and a first digital preprocessor 148. The second receiver path includes a second analog front end 162, a second A/D converter 166 and a second digital preprocessor 168. The analog front end, the A/D converter and the digital preprocessor associated with each receiver path perform similar functions to the analog front end 12, A/D converter 16 and the digital preprocessor 18 of FIG. 1. Both the first receiver path and the second receiver path receive a data signal, which is amplified, filtered and mixed at the analog front end of the respective path. Each digital preprocessor employs the short training symbols to perform gain adjustments to the amplifier in the analog front end. The data signal from both the first path and the second path is then provided to a channel estimator and noise variance estimator 150.

The noise variance estimator determines noise variances in the first and second receiver paths. The channel estimator extracts the long training symbols from the data signal and performs channel estimation for both the first and second receiver paths. The channel response determined at the training tones is employed to determine the channel response at the data tones. The channel estimates and the noise variance estimates are provided to the data demodulator 152 for demodulation of the digital data signal. The demodulated data signal is transferred to a data postprocessing component 154 for further signal processing. The data postprocessing component 154 decodes the demodulated data signal and performs forward error correction utilizing the information provided by the data demodulator. The data postprocessing component 154 then outputs the data.

A metric analyzer 156 is employed to determine at least one performance metric associated with processing of the data signal. For example, the metric analyzer 156 can be associated with the channel estimator/noise variance estimator 150 and/or the data demodulator 152 for determining SNR or SINR of the received data signal. Alternatively, the metric analyzer 156 can be associated with the data postprocessing component 154 to determine FER or BER. The measured performance metric is employed to determine an amount and/or type of training data to be provided subsequent data packets. For example, different measured levels of a given performance metric can be employed to define the number and/or type of training symbols and/or tones desired in subsequent transmission packets.

The metric analyzer 156 provides the measured performance metric to a training determination component 170. The training determination component 170 compares the measured performance metric with one or more predetermined performance metric levels to determine the training data to be provided in subsequent packets transmitted to the receiver 140. The training determination component 170 can be an algorithm executing in a processor, a hardware device or a combination of hardware and software. The training determination component 170 provides the determined number and/or type of training symbols and/or tones to a transmitter (TX) for transmitting to the device transmitting packets to the receiver 140.

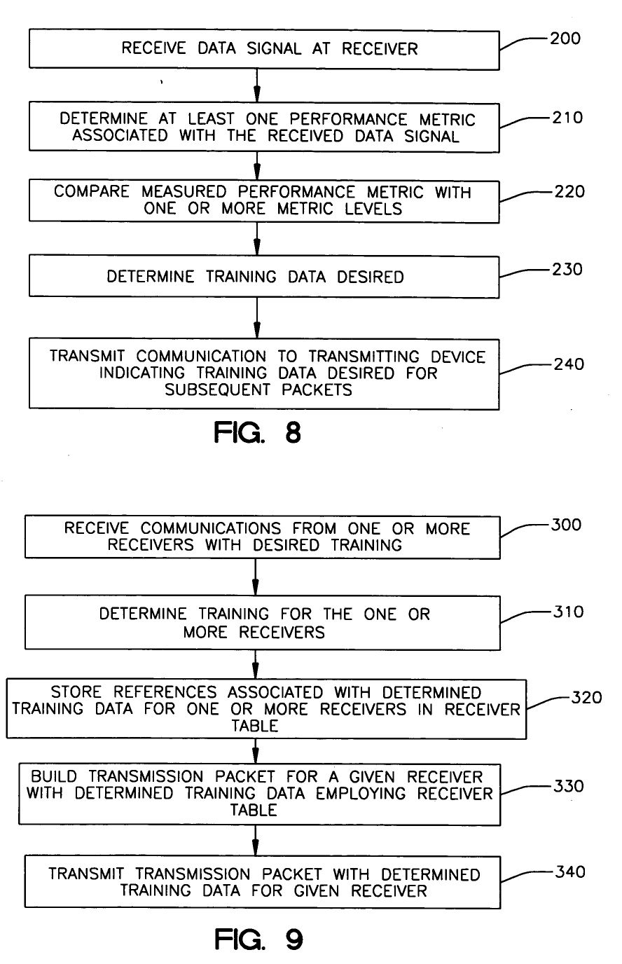

In view of the foregoing structural and functional features described above, a methodology in accordance with various aspects of the present invention will be better appreciated with reference to FIGS. 8-10. While, for purposes of simplicity of explanation, the methodologies of FIGS. 8-10 are shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect the present invention.

FIG. 8 illustrates a methodology for determining training data desired for a given receiver in accordance with an aspect of the present invention. The receiver can be part of a MCU associated with a wireless system. The methodology begins at 200 where a data signal is received at a receiver. The data signal can be received from an access point or base station associated with a wireless system. At 210, the receiver determines at least one performance metric associated with the received data signal. The at least one performance metric can be, for example, SNR, SINR, FER, BER or other receiver performance metric. At 220, the measured performance metric is compared to one or more predetermined performance metric levels. The methodology then proceeds to 230. At 230, training data is determined based on the comparison of the measured metric to the one or more performance metric levels. The training data can be in the form of a number of and/or type of additional training symbols and/or tones to be transmitted with subsequent packets. The additional training data can be in the form of a predetermined training sequence. A given training sequence can include the same or different types of training symbols and/or tones (e.g., time orthogonal, time switched, frequency orthogonal and frequency switched training sequences). The training data can be in the form of an adjustment (more or less) to an initial amount and/or type of training data. The methodology then proceeds to 240. At 240, an MCU associated with the receiver transmits a communication to the transmitting device indicating the training data that the receiver desires for subsequent packets transmitted from the transmitting device.

FIG. 9 illustrates a methodology for building and transmitting packets with determined training data in accordance with an aspect of the present invention. The methodology begins at 300, where an access point or base station receives communications from one or more receivers indicating the desired training data for subsequent packet transmissions. The training data can be in the form of a number of and/or type of additional training symbols and/or tones to be transmitted with subsequent packets. The additional training data can be in the form of a predetermined training sequence. The training data can be in the form of an adjustment to an amount and/or type of training data relative to an initial amount and/or type.

At 310, the amount and/or type of training data is determined for the one or more receivers. At 320, the access point or base station stores one or more indicators of the determined training data associated with one or more receivers in a receiver table. The indicators define a number of and/or type of training symbols and/or tones to be provided in subsequent packets of associated receivers. At 330, the access point or base station builds a transmission packet for a given receiver with the determined training data by employing the receiver table. At 340, the access point or base station transmits the transmission packet to the given receiver with the determined training data.

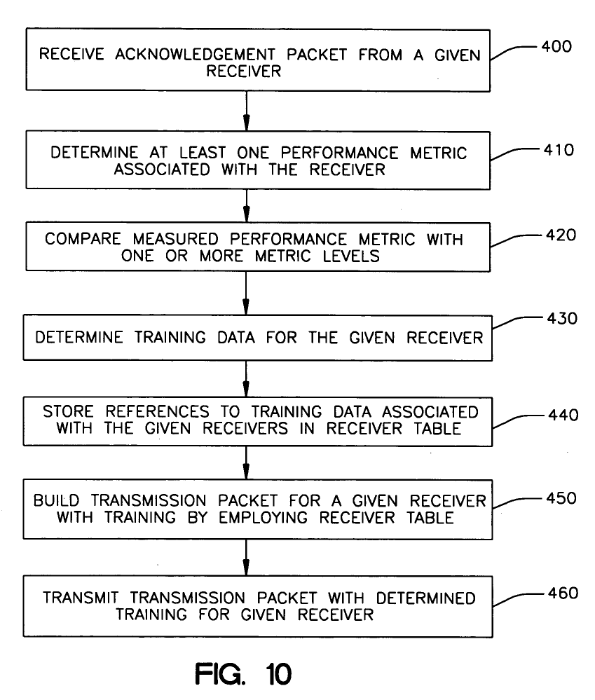

FIG. 10 illustrates another methodology for determining training data in accordance with an aspect of the present invention. The methodology begins at 400 where an access point or base station receives an acknowledgement packet from a MCU associated with a given receiver. At 410, the access point or base station determines at least one performance metric associated with the receiver. For example, the access point can determine the SNR or SINR of the acknowledgement packet to determine the SNR or SINR of the receiver. At 420, the measured performance metric is compared to one or more predetermined performance metric levels. The methodology then proceeds to 430. At 430, a desired amount and/or type of training data is determined for the given receiver based on the comparison of the measured metric to the one or more performance metric levels for the given receiver. The training data can be a specified number and/or type of additional training symbols and/or tones, or an adjustment to an initial amount and/or type of additional training symbols and/or tones. The methodology then proceeds to 440.

At 440, the access point or base station stores an indicator of the number and/or type of training symbols and/or tones for the given receiver in a receiver table. At 450, the access point or base station builds a transmission packet for a given receiver with the number and/or type of training symbols and/or tones employing the receiver table. At 460, the access point or base station transmits the transmission packet with the determined training data for the given receiver.

It is to be appreciated the methodologies of FIGS. 8-10 associated can be repeated for a plurality of receivers and MCUs. Additionally, the methodologies of FIGS. 8-10 can be performed at initialization of a wireless communication system or entrance into the wireless communication system or be dynamically modified based on operating condition changes for any receiver within the wireless communication system.

What has been described above includes exemplary implementations of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications, and variations that fall within the spirit and scope of the appended claims.

What is claimed is:

1. A communication system comprising:
a metric analyzer that measures at least one performance metric associated with at least a portion of a received data packet; and
a training determination component that determines training data to be transmitted in at least one subsequent data packet based on the measured at least one performance metric.

2. The system of claim 1, wherein the at least one performance metric [DPM1]comprises at least one of signal-to-noise ratio, signal-to-interference plus noise ratio, frame error rate and bit error rate.

3. The system of claim 1, wherein the training data comprises at least one of a number of additional training symbols, a number of additional training tones, a type of additional training data and an adjustment to one of an amount and type of initial training data.

4. The system of claim 1, wherein the training data comprises at least one of time orthogonal, time switched, frequency orthogonal and frequency switched training types.

5. The system of claim 1, wherein the metric analyzer and the training determination component are part of a receiver.

6. The system of claim 5, wherein the receiver is a multi-data path apparatus having a plurality of antennas coupled to a plurality of data paths.

7. The system of claim 1, wherein the metric analyzer and the training determination component are part of an access point.

8. The system of claim 7, further comprising:
a receiver table comprising an indicator of training data to be provided in subsequent packets for each of a plurality of receivers; and
a packet builder that employs the receiver table to retrieve the training data for a respective receiver in building a transmission packet for the respective receiver.

9. The system of claim 1, wherein the training determination component invokes a communication to an access point indicating at least one of additional training data, a type of additional training data and an adjustment to training data to be transmitted in the at least one subsequent data packet.

10. The system of claim 1, wherein the measuring of the at least one metric by the metric analyzer and the determination of training data to be transmitted in at least one subsequent data packet is performed one of at initialization and dynamically.

11. The system of claim 1, wherein the training determination component determines training data to be transmitted in the at least one subsequent data packet by comparing the measured at least one performance metric to at least one predefined performance metric level.

12. A system for determining training data to provided in transmitted data packets, the system comprising:
means for measuring a performance metric associated with a received data packet;
means for determining training data to be provided in subsequently transmitted data packets based on the measured performance metric; and
means for communicating an indication of the determined training data to be provided in subsequently transmitted data packets.

13. The system of claim 12, wherein the means for determining training data determines one of a number of additional training symbols, a number of additional training tones, a type of additional training data and an adjustment to one of an amount and type of initial training data to be provided in subsequent data packets transmitted to a given receiver.

14. The system of claim 11, wherein the means for determining training data compares the measured metric to at least one predetermined performance metric level to determine training data to be provided in subsequent transmitted data packets.

15. The system of claim 11, further comprising means for maintaining a table of indicators of training data to be provided in subsequently transmitted data packets to each of a plurality of receivers receiving transmitted data packets.

16. The system of claim 15, further comprising means for building packets, wherein the means for building packets employs the table of indicators to determine training data to be provided in subsequently transmitted data packets upon building a data packet for transmitting to a given receiver.

17. A packet structure comprising:
a preamble portion having a plurality of short training symbols and a plurality of long training symbols;
a header portion having a plurality of parameters defining the packet structure;
a data portion having a plurality of data symbols; and
an additional training data portion for providing additional training data in the packet structure.

18. The packet structure of claim 17, further comprising an additional training definition field that defines at least one of a number of additional training symbols, a number of additional training tones and training data types in the additional training data portion.

19. The packet structure of claim 18, wherein the additional training data portion and the additional training definition field reside in one of the preamble portion and the data portion.

20. The packet structure of claim 17, wherein the additional training data portion resides in one of the preamble portion and the data portion.

21. A method for determining training data to be provided in data packets transmitted to a receiver, the method comprising:
measuring at least one performance metric associated with data received at a receiver;
comparing the at least one performance metric to at least one predetermined performance metric level; and
determining training data to be provided in data packets transmitted to the receiver based on the comparison.

22. The method of claim 21, further comprising communicating an indication of the determined training data to an access point that is transmitting data packets to the receiver.

23. The method of claim 21, wherein the at least one performance metric comprises [DPM2]at least one of signal-to-noise ratio, signal-to-interference plus noise ratio, frame error rate and bit error rate.

24. The method of claim 21, wherein the training data comprises at least one of a number of additional training symbols, a number of additional training tones, a type of additional training data and an adjustment to at least one of an amount and type of initial training data.

25. The system of claim 21, wherein the training data comprises at least one of time orthogonal, time switched, frequency orthogonal and frequency switched training types.

26. The method of claim 21, further comprising:
building a receiver table that stores indicators of training data to be provided to each of a plurality of receivers; and
building packets for a given receiver with the training data employing the receiver table.

27. The method of claim 21, wherein measuring at least one performance metric further comprises measuring at least one performance metric associated with an acknowledgement packet received from the receiver.

28. A method for transmitting data packets with training data, the method comprising:
receiving an indication of training data to be provided in subsequently transmitted data packets for a given receiver;
building a data packet to be transmitted to the given receiver with the determined training data in the data packet; and
transmitting the data packet with the determined training data to the given receiver.

29. The method of claim 28, further comprising:
measuring at least one performance metric associated with data received at the given receiver;
comparing the at least one performance metric to at least one predetermined performance metric level; and
determining the training data to be provided in transmitted data packets to the given receiver based on the comparison.

30. The method of claim 28, further comprising:
measuring at least one performance metric associated with a communication received from a communication unit associated with a given receiver; and
comparing the at least one performance metric to at least one predetermined performance metric level to determine the training data to be provided in transmitted data packets to the given receiver.

31. The method of claim 28, further comprising:
receiving communication from each of a plurality of receivers indicating the training data to be provided for subsequently transmitted data packets to each respective receiver of the plurality of receivers;
storing indicators of the training data for each of the plurality of receivers in a table; and
employing the table for a respective receiver during building of subsequently transmitted data packets for the respective receiver.

32. The method of claim 28, wherein the training data comprises at least one of a number of additional training symbols, a number of additional training tones, a type of additional training data and an adjustment to at least one of an amount and type of training data.
